(19) United States
(12) Patent Application Publication
(10) Pub. No.: US 2005/0202680 A1
(43) Pub. Date: Sep. 15, 2005

(54) Method for shrinking a dimension of a gate

(76) Inventors: Yao-Chia Yeh, Hsin-Chu City (TW); Hsiao-Wen Chuang, Hsin-Chu City (TW); Chien-Nan Tu, Kaohsiung City (TW); Hsuan-Sheng Tung, Tainan (TW)

Correspondence Address: LOWE HAUPTMAN GILMAN & BERNER, LLP, Suite 310, 1700 Diagonal Road, Alexandria, VA, 22314, US

(21) Appl. No.: 10/799,687

(22) Filed: Mar. 15, 2004

(51) Int. Cl. H01L 21/336

(52) U.S. Cl. 438/694; 438/197; 438/770

(57) ABSTRACT

A method for shrinking a dimension of a gate is provided that utilizes a thermal oxidation to form an oxide layer on a semiconductor substrate and a gate. Controlling the thickness of the oxide layer on the gate will control the channel length of a gate. The oxide layer on the gate is stripped by a suitable etching solution and then shrinkage of the dimension of the gate is achieved. That is, an ability of a photolithography is overcome, moreover; shrinking the dimension of the gate to reach an advanced process by the most economical method.

### BACKGROUND OF THE INVENTION

1. Field of the Invention

The present invention relates to a method for shrinking the dimension of a gate, and more particularly to a method for forming an oxide layer on the gate so as to consume it so that the dimension of the gate is shrunk.

2. Description of the Prior Art

MOS transistor (Metal-Oxide-Semiconductor Transistor) is presently the most important unit construction in the VLSI (Very Large Scale Integrated). The basic structure of the MOS includes a capacitor, a source and a drain, which are located on two sides of the capacitor, wherein a structure of the capacitor is a gate. Typically, the gate consists of a polysilicon, a silicon dioxide and a silicon substrate. Today, one of the important drivers for increased performance in computers is the high level of integration in circuits. This is accomplished by miniaturizing or shrinking device sizes on a given chip. Shrinking the dimension of the gate will cause the shape or volume of a die to be reduced. After shrinking the dimension of the die, the amount of the die of a wafer can be improved. Thus, the throughput is enhanced.

In logic product applications, the smaller gate structure means that having the faster handling speed and a higher integrity of semiconductor devices. Therefore, the production in gate structures with a small dimension will be the most important trend in the present day. Today, control of the transistor gate critical dimension (CD) on the order of a few nanometers is a top priority in many advanced IC fabs. Each nanometer deviation from the target gate length translates directly into the operational speed to these devices. That is, a photolithography and etching process are the choke point of the semiconductor process. As a result the fabrication costs are getting more expensive, an improvement of apparatus and processes of the semiconductor processes in logic application has become imperative. The photolithography is the most influenced step of the semiconductor processes, which determines the structure about MOS transistor. In semiconductor industry, MOS transistors whether or not have the smaller word line that depends on the development of the photolithography process. However, an etching process is focused on the etching of the poly gate and the silicon dioxide so that the ability of the patterning in logic circuit can be improved. Moreover, shrinking the semiconductor is getting so precise that the integrity of the IC is enhanced.

FIG. 1A to FIG. 1C is the conventional process of a poly gate. At first, referring to FIG. 1A, providing a semiconductor substrate 101, for instance a p-type silicon substrate. In the p-type silicon substrate that comprises an isolation process, for instance utilizing a shallow trench isolation process to from the plurality of shallow trenches as a plurality of the isolation zone 103 in the two sides of the semiconductor substrate 101. The plurality of the isolation zone 103 can provide the isolation between a transistor and another transistor. Next, forming a thin oxide layer 105, for instance a silicon dioxide layer and a polysilicon layer 107 on the plurality of the isolation zones 103 and a the semiconductor substrate 101 respectively.

Following, as shown in FIG. 1B. When the main thin films are successively deposited or grown to create the structure of the MOS transistor, a photoresist layer 111 is deposited on the polysilicon layer 107, and the photoresist layer 111 is utilized to defined a pattern on a gate of the MOS transistor. Utilizing a pattern transferring process by a mask with a specific pattern and then the specific pattern is transferred on the photoresist layer 111. Next, utilizing a development process to form a patterning photoresist layer 111 on the polysilicon layer 107.

Subsequently, utilizing the patterning photoresist layer 111 as a mask and performing an etching process on the polysilicon layer 107 and the oxide layer 105. Then, a polygate 108 is formed on the surface of the semiconductor substrate 101 that comprises the polysilicon layer 107 and oxide layer 105, as shown in FIG. 1C. The etching process for forming the structure of the polygate 108 is described as follows: At first, utilizing the photoresist layer 111 as a mask to remove the exposed polysilicon layer 107 and oxide layer 105 by a way of dry etching. Then, stripping the photoresist layer 111 to form the polygate 108 on the semiconductor substrate 101.

As a result, the dry etching process utilizes the photoresist layer 111 as a mask in order to selectively strip the thin film on the MOS transistor. However, the Vₜ (threshold voltage) and I_{dsat} (saturated drain current) of the MOS transistor depends on the channel length of the gate, which means depending on the width of the photoresist layer. Moreover, the resolution of the word line of the gate is limited to the width of the photoresist layer. When the photolithography process could not surmount the technique in the present time, the devices on the MOS transistor could not toward having a smaller dimension.

Due to the fact of utilizing the conventional photolithography process in order to shrink the dimension of a gate that is easily limited to the ability of the photolithography of a photoresist layer. Hence, a semiconductor process that can shrink the dimension of the gate is required.

### SUMMARY OF THE INVENTION

It is an objective of the present invention to provide a method for shrinking a dimension of a gate that utilizes a way of the thermal oxidation, which can stably and uniformly form an oxide layer on the gate. By controlling the thickness of the oxide layer, the word line of the gate can be controlled. Moreover, shrinking the dimension of the gate is achieved.

It is another objective of the present invention to provide a method for shrinking a dimension of a gate that utilizes an etching solution, which can stably consume the oxide layer on the gate and not damage the gate, furthermore; the yield is improved.

It is further objective of the present invention to provide a method for shrinking a dimension of a gate that can overcome the limitations of a traditional photolithography process. It is an economical and unsophisticated method for shrinking the dimension of the gate.

In order to achieve the objects as mentioned above, the present invention provides a method for shrinking a dimension of a gate. At first, providing a semiconductor substrate, for instance a p-type silicon substrate. In the semiconductor substrate comprises plurality of the isolation zones therein, for instance a plurality of the shallow trenches, which are placed on the two sides of the semiconductor substrate. Then, depositing a silicon dioxide layer, a polysilicon layer and a photoresist layer on the semiconductor substrate respectively. Next, utilizing the photoresist layer as a mask in order to etch the polysilicon layer and silicon dioxide layer by a way of the dry etching process, for instance reactive ion etch (RIE) method. After stripping the photoresist layer, a structure of a gate is formed on the semiconductor substrate, moreover, placed between the plurality of the isolation zones. Thereafter, an oxide layer is deposited on the surface of the semiconductor substrate and the gate by a process of thermal oxidation. The thickness of the oxide layer can refer to another thickness of the oxide layer, which is on a surface of a dummy wafer. By calculation, the oxide layer on the gate can be controlled, furthermore, control the word line of the gate. Finally, utilizing an etching solution, for instance a DHF solution (HF in deionized water) or a BOE solution (buffered oxide etch) to remove the oxide layer and achieve the object for shrinking the dimension of the gate.

### BRIEF DESCRIPTION OF THE DRAWINGS

The objectives and features of the present inventions as well as advantages thereof will become apparent from the following detailed description, considered in conjunction with the accompanying drawings. It is to be understood, however, that the drawings, which are not to scale, are designed for the purpose of illustration and not as a definition of the limits of the invention, for which reference should be made to the appended claims.

The present invention can be best understood through the following description and accompanying drawings, wherein:

FIG. 1A to 1C shows schematically cross-sectional views of various steps of a conventional method for manufacturing the polygate; and

FIG. 2A to 2E shows schematically cross-sectional views of various steps of one embodiment according to the present invention that a method for shrinking the dimension of the gate.

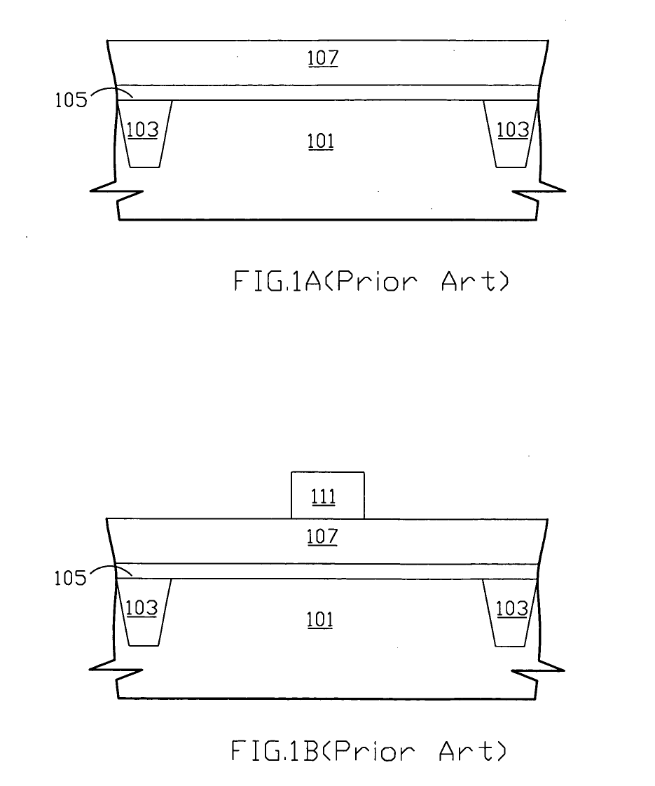

### DESCRIPTION OF THE PREFERRED EMBODIMENT

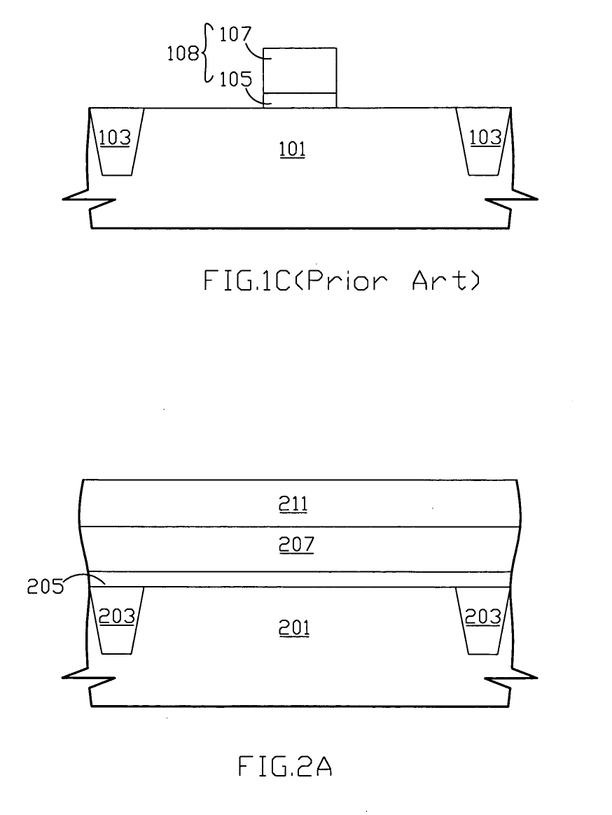

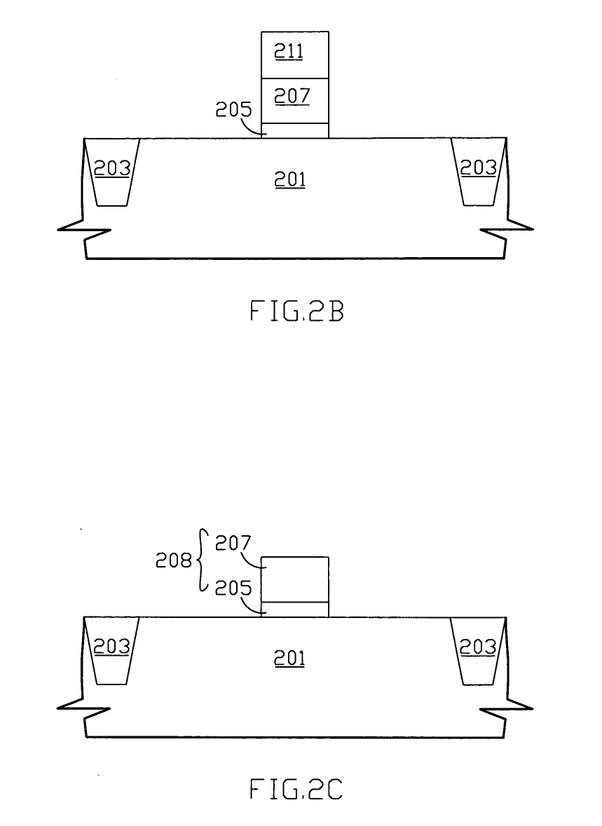

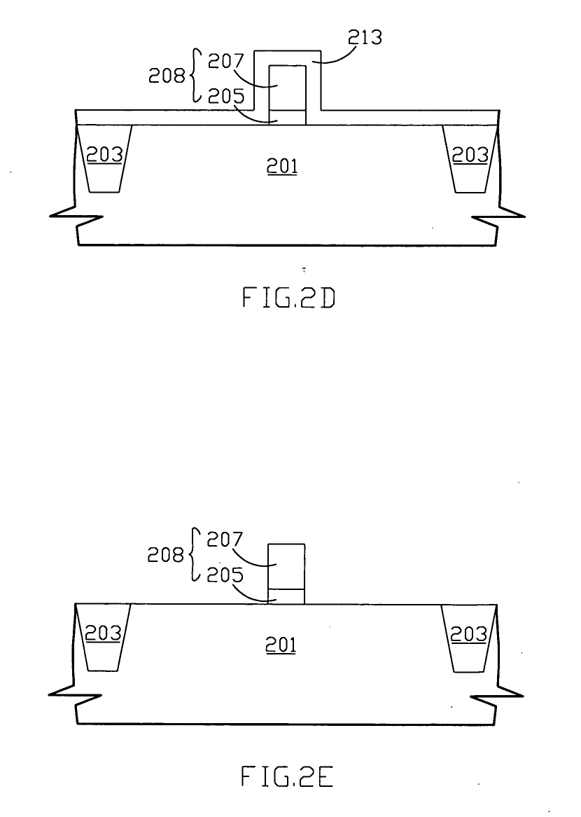

Preferred embodiments of this invention will be explained with reference to the drawings of FIG. 2A to FIG. 2E. Referring to FIG. 2A, providing a semiconductor structure firstly, wherein comprises a semiconductor substrate 201, for instance a p-type silicon substrate. An oxide layer (not illustrated) is deposited on the semiconductor substrate 201; for instance silicon dioxide. A dielectric layer (not illustrated) is deposited on the oxide layer; for instance silicon nitride. The oxide and nitride layers are defined as a mask layer of an active region in the semiconductor substrate 201. Thereafter, etching a portion of the mask layers through a dry etching process, and dry etching is performed and stopped within the semiconductor substrate 201 so as to form a plurality of shallow trench. Then, the shallow trench surface has an oxidation so that the damage on the shallow trench surface will be filled and repaired. Subsequently, performing the trench filling with a silicon dioxide by way of a chemical vapor deposition (CMP) technique and planarizing the trench oxide layer with a chemical mechanical polishing (CMP) technique so that a plurality of isolation 203 is formed, which can provide a isolation between each semiconductor device through subsequent processes.

Following, a silicon dioxide layer 205, a polysilicon layer 207 and a photoresist layer 211 is respectively deposited on the surface of the semiconductor substrate 201 and plurality of the isolation zones 203. Each thin film as mentioned above is deposited by a suitable method of vapor deposition, for instance low pressure chemical vapor deposition (LPCVD), atmospheric pressure chemical vapor deposition (APCVD) or high density plasma chemical vapor deposition (HDPCVD). The polysilicon layer 207 is used a doping process such as doping a plurality of ions therein to reduce the resistance of the polysilicon layer 207, and enhance the conductivity.

Subsequently, referring to FIG. 2B. A mask with specific patterns, for instance a mask with a pattern as a gate and then the specific pattern is performed a pattern transferring on the photoresist layer 211 by photolithography and exposed process. Next, removing the exposed photoresist layer 211 by development process in order to form a patterning photoresist layer 211 on the surface of the semiconductor layer 209. Following that, utilizing the patterning photoresist layer 211 as a mask and etching each thin film to form a gate on the surface of the semiconductor substrate 201. However, each layer of thin film has different material so the etching rate could be different that requires a different etching process. At first, utilizing the patterning photoresist layer 211 as a mask to perform an etching process to the polysilicon layer 207, wherein a reactive gas, which has chlorine atom is utilized such as HCl or SiCl₄ etc. Etching the uncovered polysilicon layer 207 with RIC method until the silicon dioxide layer 205 is partially exposed. After accomplishing the etching process to the polysilicon layer 207, the patterning photoresist layer 211 is utilized as a mask again so that the silicon dioxide layer 205 is etched until the surface of the semiconductor substrate 201 is partially exposed. In which, utilizing a reactive gas that has a fluorine atom such as CF₄.

Following, referring to FIG. 2C. After stripping the patterning photoresist layer 211, a structure of a gate 208 is formed and between two isolation zones 203 that comprises silicon dioxide layer 205 and polysilicon layer 207. Due to the fact that the word line of the gate is getting smaller and smaller by the development of the shrinkage in the semiconductor processes so that the gross amount of the transistor on the chip can be enhanced. By shrinking the word line of the gate 208, the handling speed of the transistor is enhanced. However, when the process is getting into the higher level, the word line of the gate 208 is limited to a resolution of a stepper in the photolithography process. Hence, the patterning photoresist layer 211 can not further shrink so that the gate 208 can not develop the process of having smaller word line.

Accordingly, in order to resolve the problem with shrinking the width of the photoresist because of ability of the photolithography result in the gate can not have the smaller word line. As shown in FIG. 2D, this present invention utilizes a thermal oxidation method, for instance a dry oxidation or a wet oxidation method and then forming an oxide layer 213 on the surface of the semiconductor substrate 201 and the gate 208. The formation of the oxide layer 213 utilizes the silicon atom that reacts with aqueous and oxygenic atoms to perform an oxidation, which means performing the oxidation on the surface of the gate 208 and semiconductor substrate 201. In which, an oxide layer 213, which comprises silicon dioxide, is formed on the surface of the gate 208 and semiconductor substrate 201. As a result, the oxidation is performed on the surface of the silicon chip so that the silicon atom on the silicon chip is on the reactant. Moreover, the thermal reaction will consume a portion of the gate 208 and the semiconductor substrate 201. The oxide layer 213 is deposited by way of the conformal. That means the thickness of the oxide layer 213 is the same, which on the surface of the semiconductor substrate 201, sidewall and the top of the gate 208. Besides, controlling the thickness of the oxide layer 213 utilizes a process monitor apparatus, which can control the process of temperature, pressure and gas flow etc. That is, a dummy wafer is utilized as a reference that the same processes are performed to form an oxide layer thereon, and monitoring the growth of the oxide layer on the dummy wafer. Then, the thickness of the oxide layer 213, which is on the surface of the gate 208 and the semiconductor substrate 201, is successively realized by calculation. Besides, the formation of the oxide layer 213 on the surface of the gate 208 and semiconductor substrate 201 can fill in the damage on the gate 208 because of plasma etching.

After forming the oxide layer 213 on the semiconductor substrate 201 and the gate 208, referring to the FIG. 2E subsequently. Removing the oxide layer 213 by a suitable etching solution, for instance a hydrofluoric acid solution or a BOE solution (buffered oxide etch), in order to shrink the dimension of the gate 208. The hydrofluoric acid solution, such as DHF solution, is utilized HF diluted in deionized water, and the BOE solution is utilized HF diluted in NH₄F. In which, the BOE solution can achieve the etch-stop effect and not damage the semiconductor substrate 201. Besides, the oxidation will consume a portion of the silicon on the surface of the gate 208 and the semiconductor substrate 201, moreover; a process monitor can control the thickness of the oxide layer 213. Hence, the word line of the gate 208 can be precisely controlled and a shrunken gate 208 on the surface of the semiconductor substrate 201 is obtained. The gate 208 comprises polysilicon layer 207 and the silicon dioxide layer 205. Finally, the present invention for shrinking the dimension of the gate is accomplished.

According to the preferred embodiment of this invention, which can realize one of the advantages of the present invention that a method for shrinking the dimension of the gate is provided. That is, utilizing a thermal oxidation to simultaneously form an oxide layer on a semiconductor substrate and a gate. As a result, the oxide layer is grown on the surface of the semiconductor substrate, a portion of the polysilicon layer also have an oxidation thereon, that is to say; the thickness and width of the gate and polysilicon layer will be consumed. When a dummy wafer, which has the same recipe with this present invention to form an oxide layer thereon, accurately controls the thickness of the oxide layer. That is, utilizing the thickness of the oxide layer on the dummy wafer as a reference to exactly calculate the thickness of the oxide layer on the gate and semiconductor substrate by calculation. Hence, the word line of the gate can be precisely and effectively shrunk. Besides, the oxide layer on the gate and semiconductor substrate is stripped by a suitable etching solution, which can stably consume the oxide layer and not damage the gate, furthermore; shrinkage of the dimension of the gate is achieved. That is, utilizing the method of the present invention has overcame the problem with the resolution of the word line of the gate is limited to the width of the photoresist layer, and shrinking the dimension of the gate to reach an advanced process by the economical and convenient method.

The preferred embodiments are only used to illustrate the present invention, not intended to limit the scope thereof. Many modifications of the preferred embodiments can be made without departing from the spirit of the present invention.

1. A method for shrinking a dimension of a gate, comprising;
providing a semiconductor structure;
forming a semiconductor gate on said semiconductor structure;
forming a first oxide layer on a surface of said semiconductor gate and said semiconductor structure, wherein said thickness of said first oxide layer is in accordance with the thickness of a second oxide layer above a dummy wafer; and
removing said first oxide layer, wherein a etching solution is used to remove said first oxide layer.

2. The method of claim 1, wherein said semiconductor structure comprises a semiconductor substrate and a plurality of isolation zones therein.

3. The method of claim 2, wherein said semiconductor gate comprises a polysilicon layer and a gate oxide layer thereon.

4. The method of claim 3, wherein comprises a plurality of ions doped therein.

5. The method of claim 1, wherein said first oxide layer comprises utilizing a method of thermal oxidation to deposit.

6. The method of claim 1, wherein said first oxide layer comprises utilizing a method of conformal to deposit.

7. The method of claim 1, wherein said etching solution comprises a hydrofluoric acid solution.

8. The method of claim 7, wherein said hydrofluoric acid solution comprises a DHF solution (HF in deionized water).

9. The method of claim 1, wherein said etching solution comprises a BOE solution (Buffered Oxide Etch).

10. The method of claim 9, wherein said BOE solution comprises a HF/NH₄F buffered solution.

11. A method for shrinking a dimension of a gate, comprising;
providing a semiconductor substrate;
forming a first oxide layer on said semiconductor substrate;
forming a polysilicon layer on said first oxide layer;
forming a photoresist layer on said polysilicon layer;
patterning said photoresist layer;
etching a portion of said polysilicon layer and said first oxide layer until a portion of said semiconductor substrate is exposed, wherein said patterned photoresist layer is utilized as a mask;
removing said patterned photoresist layer;
performing an oxidation on a surface of said polysilicon layer, said first layer and said semiconductor substrate to form a second oxide layer on said surface of said polysilicon layer, said first oxide layer and said semiconductor substrate, wherein said thickness of said second oxide layer is in accordance with the thickness of a third oxide layer above a dummy wafer; and
removing said second oxide layer, wherein a etching solution is used to remove said second oxide layer.

12. The method of claim 11, wherein said second oxide layer comprises utilizing a method of thermal oxidation to deposit.

13. The method of claim 11, wherein said second oxide layer comprises utilizing a method of conformal to deposit.

14. The method of claim 11, wherein said etching solution comprises a hydrofluoric acid solution.

15. The method of claim 14, wherein said hydrofluoric acid solution comprises a DHF solution (HF in deionized water).

16. The method of claim 11, wherein said etching solution comprises a BOE solution (Buffered Oxide Etch).

17. The method of claim 16, wherein said BOE solution comprises a HF/NH₄F buffered solution.
